(19) United States
(12) Patent Application Publication
(10) Pub. No.: US 2025/0071912 A1
(43) Pub. Date: Feb. 27, 2025

(54) ELECTRONIC DEVICE AND MANUFACTURING METHOD THEREOF

(71) Applicant: InnoLux Corporation, Miao-Li County (TW)

(72) Inventors: Ming-Chih TSAI, Miao-Li County (TW); Yu-Heng CHEN, Miao-Li County (TW)

(21) Appl. No.: 18/782,870

(22) Filed: Jul. 24, 2024

(30) Foreign Application Priority Data
Aug. 22, 2023 (CN) 202311061421.0

(51) Int. Cl. H05K 3/46; H05K 1/02; H05K 3/06

(52) U.S. Cl. CPC H05K 3/4644; H05K 1/0298; H05K 3/067

(57) ABSTRACT

A method of manufacturing an electronic device is provided. The method includes providing a substrate, disposing a composite conductive layer on the substrate, and patterning the composite conductive layer into a composite conductive pattern in two wet etching steps. Moreover, the two wet etching steps use different etching solutions.

### CROSS REFERENCE TO RELATED APPLICATIONS

This application claims the benefit of China Application No. 202311061421.0, filed Aug. 22, 2023, the entirety of which is incorporated by reference herein.

### BACKGROUND

### Technical Field

The present disclosure is related to an electronic device and a manufacturing method thereof.

### Description of the Related Art

Electronic devices with power-saving (or power-consumption reducing) functions such as reflective displays have become a trend. The composite conductive patterns in these electronic devices may be composed of multiple material layers with widely different materials and properties (e.g., etching rates) due to their specific purposes (e.g., shielding functions, or reducing reflection). When multiple material layers with widely different etching rates are patterned, an overhang structure can easily be formed, causing the insulating layer that is subsequently formed on it to crack, or causing part of the composite conductive pattern to break and to make electrical contact with adjacent circuit components, thereby creating a short circuit.

Therefore, how to improve the process yield and structural reliability of composite conductive patterns is still one of the current research topics in the industry.

### SUMMARY

In accordance with some embodiments of the present disclosure, a method of manufacturing an electronic device is provided. The method includes providing a substrate. The method includes disposing a composite conductive layer on the substrate. The method includes patterning the composite conductive layer into a composite conductive pattern in two wet etching steps. Moreover, the two wet etching steps use different etching solutions.

In accordance with some embodiments of the present disclosure, an electronic device is provided. The electronic device includes a substrate and a composite conductive pattern. The composite conductive pattern is disposed on the substrate. The composite conductive pattern includes a first conductive pattern and a second conductive pattern. The second conductive pattern is disposed on the first conductive pattern. The second conductive pattern exposes a portion of an upper surface of the first conductive pattern. Furthermore, the electronic device includes an insulating layer disposed on the second conductive pattern and contacting the portion of the upper surface of the first conductive pattern exposed by the second conductive pattern. The upper surface of the first conductive pattern has a first surface width and the portion exposed by the second conductive pattern has a first width. The first width and the first surface width comply with the following formula: 0<the first width≤the first surface width×⅕.

A detailed description is given in the following embodiments with reference to the accompanying drawings.

### BRIEF DESCRIPTION OF THE DRAWINGS

The disclosure may be more fully understood by reading the subsequent detailed description and examples with references made to the accompanying drawings, wherein:

FIG. 1 is a cross-sectional diagram of an electronic device in accordance with some embodiments of the present disclosure;

FIGS. 2A to 2F are cross-sectional diagrams of some elements of an electronic device during the intermediate stages of the manufacturing process in accordance with some embodiments of the present disclosure;

FIGS. 3A to 3E are cross-sectional diagrams of some elements of an electronic device during the intermediate stages of the manufacturing process in accordance with some embodiments of the present disclosure;

FIGS. 4A to 4C are cross-sectional diagrams of some elements of an electronic device during the intermediate stages of the manufacturing process in accordance with some embodiments of the present disclosure;

FIGS. 5A to 5E are cross-sectional diagrams of some elements of an electronic device during the intermediate stages of the manufacturing process in accordance with some embodiments of the present disclosure;

FIGS. 6A to 6D are cross-sectional diagrams of some elements of an electronic device during the intermediate stages of the manufacturing process in accordance with some embodiments of the present disclosure;

FIG. 7A and FIG. 7B are cross-sectional diagrams of some elements of an electronic device in accordance with some embodiments of the present disclosure.

### DETAILED DESCRIPTION

The electronic device and the method of manufacturing the same according to the present disclosure are described in detail in the following description. It should be understood that in the following detailed description, for purposes of explanation, numerous specific details and embodiments are set forth in order to provide a thorough understanding of the present disclosure. The elements and configurations described in the following detailed description are set forth in order to clearly describe the present disclosure. These embodiments are used merely for the purpose of illustration, and the present disclosure is not limited thereto. In addition, different embodiments may use like and/or corresponding numerals to denote like and/or corresponding elements in order to clearly describe the present disclosure. However, the use of like and/or corresponding numerals of different embodiments does not suggest any correlation between different embodiments.

It should be understood that relative expressions may be used in the embodiments. For example, “lower”, “bottom”, “higher” or “top” are used to describe the position of one element relative to another. It should be appreciated that if a device is flipped upside down, an element that is “lower” will become an element that is “higher”. The present disclosure can be understood by referring to the following detailed description in connection with the accompanying drawings. The drawings are also regarded as part of the description of the present disclosure. It should be understood that the drawings of the present disclosure may be not drawn to scale. In fact, the size of the elements may be arbitrarily enlarged or reduced to clearly represent the features of the present disclosure.

Furthermore, the expression “a first material layer is disposed on or over a second material layer” may indicate that the first material layer is in direct contact with the second material layer, or it may indicate that the first material layer is in indirect contact with the second material layer. In the situation where the first material layer is in indirect contact with the second material layer, there may be one or more intermediate layers between the first material layer and the second material layer. However, the expression “the first material layer is directly disposed on or over the second material layer” means that the first material layer is in direct contact with the second material layer, and there is no intermediate element or layer between the first material layer and the second material layer.

Moreover, it should be understood that the ordinal numbers used in the specification and claims, such as the terms “first”, “second”, etc., are used to modify an element, which itself does not mean and represent that the element (or elements) has any previous ordinal number, and does not mean the order of a certain element and another element, or the order in the manufacturing method. The use of these ordinal numbers is to make an element with a certain name can be clearly distinguished from another element with the same name. Claims and the specification may not use the same terms. For example, the first element in the specification may refer to the second element in the claims.

In accordance with the embodiments of the present disclosure, regarding the terms such as “connected to”, “interconnected with”, etc. referring to bonding and connection, unless specifically defined, these terms mean that two structures are in direct contact or two structures are not in direct contact, and other structures are provided to be disposed between the two structures. The terms for bonding and connecting may also include the case where both structures are movable or both structures are fixed. In addition, the term “electrically connected to” or “coupled to” may include any direct or indirect electrical connection means.

In the following descriptions, terms “about”, “substantially” and “approximately” typically mean +/−10% of the stated value, or typically +/−5% of the stated value, or typically +/−3% of the stated value, or typically +/−2% of the stated value, or typically +/−1% of the stated value or typically +/−0.5% of the stated value. The expression “in a range from the first value to the second value” or “between the first value and the second value” means that the range includes the first value, the second value, and other values in between. Moreover, certain errors may exist between any two values or directions used for comparison. If the first value is equal to the second value, it implies that there may be an error of about 10% between the first value and the second value; if the first direction is perpendicular to the second direction, the angle between the first direction and the second direction may be between 80 degrees and 100 degrees; if the first direction is parallel to the second direction, the angle between the first direction and the second direction may be between 0 degrees and 10 degrees.

Throughout the present disclosure and the appended claims, certain terms are used to refer to specific elements. Those skilled in the art should understand that electronic device manufacturers may refer to the same element with different names. The present disclosure does not intend to distinguish between elements that have the same function but different names. In the specification and claims, the terms “comprising”, “including”, “having” and the like are open-ended phrases, so they should be interpreted as “including but is not limited to . . . ”. Therefore, when the terms “comprising”, “including” and/or “having” are used in the description of the present disclosure, they specify the corresponding features, regions, steps, operations and/or components, but do not exclude the existence of one or more corresponding features, regions, steps, operations and/or components.

It should be understood that in the following embodiments, without departing from the spirit of the present disclosure, the features in several different embodiments can be replaced, recombined, and mixed to complete another embodiment. The features between the various embodiments can be mixed and matched arbitrarily as long as they do not violate or conflict the spirit of the present disclosure.

Unless defined otherwise, all technical and scientific terms used herein have the same meaning as commonly understood by one of ordinary skill in the art to which this disclosure belongs. It should be appreciated that, in each case, the term, which is defined in a commonly used dictionary, should be interpreted as having a meaning that conforms to the relative skills of the present disclosure and the background or the context of the present disclosure, and should not be interpreted in an idealized or overly formal manner unless so defined.

In accordance with some embodiments of the present disclosure, a method of manufacturing an electronic device is provided, including etching steps using different etching solutions to form a composite conductive pattern, thereby improving the overhang structure produced by the composite conductive pattern having multiple layers with widely different etching rates. The method further reduces problems such as cracks in the insulating layer or short circuits caused by electrical connections with adjacent circuit elements caused by the overhang structure, thereby improving the structural reliability of the composite conductive pattern.

In accordance with the embodiments of the present disclosure, the electronic device may include a display device, a tiled device, a touch electronic device, a sensing device, a curved electronic device or a non-rectangular electronic device, but it is not limited thereto. The electronic device may, for example, include liquid crystal, light-emitting diode, fluorescence, phosphor, other suitable display media, or a combination thereof, but it is not limited thereto. The display device may be a non-self-luminous display device or a self-luminous display device. The electronic device may include passive components and active components, such as capacitors, resistors, inductors, diodes, transistors, and the like. The diode may include a light-emitting diode (LED) or a photodiode. The light-emitting diode may include an organic light-emitting diode (OLED), a mini light-emitting diode (mini LED), a micro light-emitting diode (micro LED) or a quantum dot light-emitting diode (quantum dot LED), but it is not limited thereto. The tiled device may be, for example, a display tiled device, but it is not limited thereto. It should be noted that the electronic device can be any permutation and combination of the foregoing, but it is not limited thereto. In addition, the electronic device may be a bendable or flexible electronic device. In addition, the shape of the electronic device may be rectangular, circular, polygonal, with curved edges, or other suitable shapes. The electronic device may have peripheral systems such as a driving system, a control system, a light source system, etc. to support a display device, or a tiled device. For the convenience of description, the electronic device will be described below as a display device, but the present disclosure is not limited thereto.

Some variations of the embodiments will be described below. Similar reference numerals are used to identify similar elements in the various drawings and illustrated embodiments. It is understood that additional operations may be provided before, during, or after the method, and some of the described operations may be replaced or deleted for other embodiments of the method.

It should be understood that, in accordance with the embodiments of the present disclosure, an optical microscope (OM), a scanning electron microscope (SEM), a film thickness profiler (α-step), an ellipsometer or another suitable method may be used to measure the depth, thickness, width or height of each element, or spacing or distance between elements. Specifically, in accordance with some embodiments, a scanning electron microscope may be used to obtain a cross-sectional image including the elements to be measured, and the depth, thickness, width or height of each element, or spacing or distance between elements in the image can be measured.

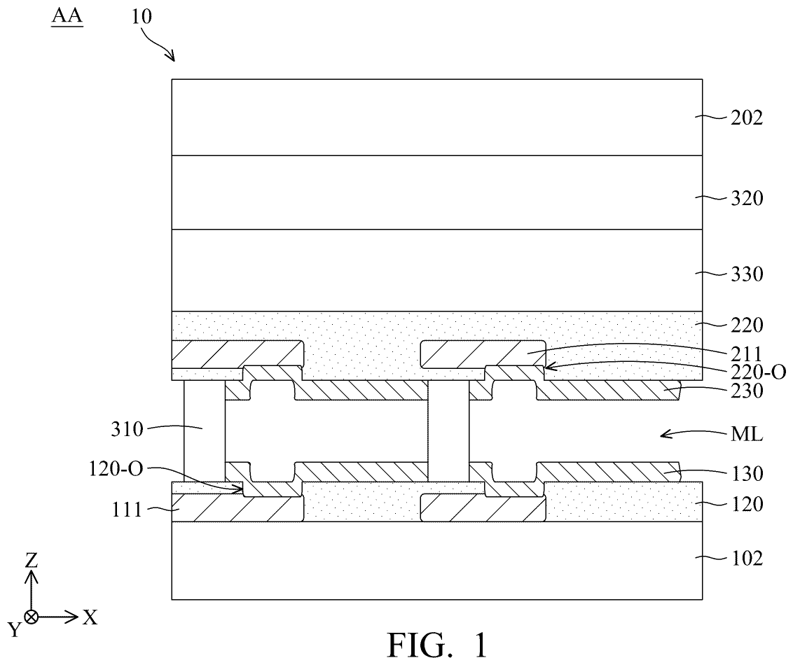

Please refer to FIG. 1, which is a cross-sectional diagram of an electronic device 10 in accordance with some embodiments of the present disclosure. It should be understood that, for clarity, some elements of the electronic device 10 may be omitted in the drawings, and only some elements are schematically shown. In accordance with some embodiments, additional features may be added to the electronic device 10 described below. Furthermore, FIG. 1 can be regarded as a partial structure of the electronic device 10 in the display area, but the present disclosure is not limited thereto. The structures described below may also be located in the peripheral area of the electronic device 10.

As shown in FIG. 1, the electronic device 10 may include a substrate 102, a substrate 202, a composite conductive pattern 111, a composite conductive pattern 211, an insulating layer 120, an insulating layer 220, an electrode layer 130, an electrode layer 230, a spacer element 310, a color filter layer 320, and an insulating layer 330. The substrate 102 may be disposed opposite to the substrate 202. The composite conductive pattern 111 may be disposed on the substrate 102. The insulating layer 120 may be disposed on the substrate 102 and the composite conductive pattern 111. The electrode layer 130 may be disposed on the insulating layer 120. The composite conductive pattern 111 and the electrode layer 130 may be electrically connected through an opening 120-O of the insulating layer 120.

As shown in FIG. 1, the insulating layer 220 and the composite conductive pattern 211 may be disposed on the substrate 202, and the electrode layer 230 may be disposed on the insulating layer 220. The composite conductive pattern 211 and the electrode layer 230 may be electrically connected through an opening 220-O of the insulating layer 220.

Furthermore, the spacer element 310 may be disposed between the insulating layer 120 and the insulating layer 220. In some embodiments, in a top-view direction of the electronic device 10 (the Z direction), the composite conductive pattern 211 and/or the composite conductive pattern 111 may, for example, overlap with the spacer element 310. In some embodiments, the color filter layer 320 and/or the insulating layer 330 may be disposed between the substrate 202 and the insulating layer 220, but it is not limited thereto. In some embodiments, the insulating layer 330 may serve as a planarization layer, but it is not limited thereto. In some embodiments, the insulating layer 330 may include an organic insulating layer or an inorganic insulating layer. In some embodiments, the electronic device 10 may further include a material layer ML (e.g., a display layer, a light-emitting layer, a radiation modulating layer, but it is not limited thereto). The material layer ML may be disposed between the substrate 102 and the substrate 202. The material layer ML may be disposed between the electrode layer 130 and the electrode layer 230. In some embodiments, the material layer ML may include any suitable liquid-crystal layer, inorganic light-emitting layer, organic light-emitting layer, etc., but it is not limited thereto. For example, the liquid-crystal layer may include nematic liquid crystal, smectic liquid crystal, cholesteric liquid crystal, blue-phase liquid crystal, another suitable liquid crystal material or a combination thereof, but it is not limited thereto. In accordance with some embodiments, an electric field may be applied to the material layer ML through the electrode layer 130 and the electrode layer 230 to change the arrangement direction and angle of the material layer ML, thereby adjusting the displayed image. It should be noted that FIG. 1 exemplarily shows that the electronic device 10 includes one material layer ML, but it is not limited thereto. The electronic device 10 may include at least one material layer ML according to needs. For example, if the electronic device 10 is a reflective display device, the electronic device 10 may include at least one material layer ML, such as multiple cholesteric liquid-crystal layers that reflect light of different colors, but it is not limited thereto. In accordance with some embodiments, the substrate 102 may serve as a driving substrate (or array substrate), and the substrate 202 may serve as a color filter substrate, but it is not limited thereto. In accordance with some embodiments, the substrate 102 may have a driving circuit (not illustrated) thereon, such as an active driving circuit. In accordance with some embodiments, the substrate 102 may have a passive driving circuit thereon. In some other embodiments (not illustrated), the color filter layer 320 and the active driving circuit (not illustrated) may be disposed on the same substrate (e.g., the substrate 102). In accordance with some embodiments, the substrate 102 and the substrate 202 may include a flexible substrate, a rigid substrate, or a combination thereof, but they are not limited thereto. In accordance with some embodiments, the substrate 102 and/or the substrate 202 may include a light-transmitting substrate, but it is not limited thereto. In accordance with some embodiments, the material of the substrate 102 and/or the substrate 202 may include glass, quartz, sapphire, ceramic, polyimide (PI), polycarbonate (PC), polyethylene terephthalate (PET), polypropylene (PP), another suitable material or a combination thereof, but it is not limited thereto. Furthermore, the material of the substrate 102 may be the same as or different from the material of the substrate 202.

In accordance with some embodiments, the composite conductive pattern 111 and/or the composite conductive pattern 211 may be located in an active area AA (including the display area, light-emitting area, radiation area or suitable functional area) of the electronic device 10, but it is not limited thereto. For example, the electronic device 10 may include a plurality of scan lines (not illustrated) and data lines (not illustrated). These scan lines (not illustrated) and data lines (not illustrated) alternately define multiple areas (e.g., sub-pixel areas or sub-functional areas), and the active area can be defined as an area encompassing these multiple areas (e.g., sub-pixel areas or sub-functional areas), but it is not limited thereto. In accordance with some embodiments, the composite conductive pattern 111 and/or the composite conductive pattern 211 may be located in a peripheral circuit area (not labeled, an area other than the active area AA) and/or the active area AA. In other words, the composite conductive pattern 111 and/or the composite conductive pattern 211 may, for example, extend from the active area AA to the peripheral circuit area (not labeled, the area outside the active area AA). In accordance with some embodiments, the composite conductive pattern 111 and the composite conductive pattern 211 may include, for example, blackened metal materials or another low-reflective metal material, but they are not limited thereto. In accordance with some embodiments, the composite conductive pattern 111 and the composite conductive pattern 211 may have low-reflective properties or shielding properties. The composite conductive pattern 111 and the composite conductive pattern 211 may, for example, be used to shield wirings or circuits formed on the substrate, but they are not limited thereto. In accordance with some embodiments, the composite conductive pattern 111 and/or the composite conductive pattern 211 may each include a plurality of conductive material layers, i.e. may have a multi-layer structure. In accordance with some embodiments, the composite conductive pattern 111 and/or the composite conductive pattern 211 may include a multi-layer structure formed by metal materials, alloy materials, oxide materials, or a combination thereof. In accordance with some embodiments, the metal material may include copper (Cu), aluminum (Al), chromium (Cr), molybdenum (Mo), yttrium (Y), tantalum (Ta), tungsten (W), gold (Au), silver (Ag), tin (Sn), nickel (Ni), platinum (Pt), titanium (Ti), iridium (Ir), rhodium (Rh), another suitable metal material, or a combination thereof, but it is not limited thereto. In accordance with some embodiments, the alloy material may include alloys of the aforementioned metal material and another suitable alloy material, but it is not limited thereto. In accordance with some embodiments, the oxide material may include chromium oxide, silicon oxynitride, molybdenum oxide, tantalum oxide, another suitable oxide material, or a combination thereof, but it is not limited thereto. The detailed structure and manufacturing method of the composite conductive pattern will be further described below.

In accordance with some embodiments, the insulating layer 120 and the insulating layer 220 may include an inorganic material, an organic material, or a combination thereof, but it is not limited thereto. In accordance with some embodiments, the inorganic material may include silicon nitride, silicon oxide, silicon oxynitride, aluminum oxide, another suitable material, or a combination thereof, but it is not limited thereto. In accordance with some embodiments, the organic material may include perfluoroalkoxy alkane (PFA), polytetrafluoroethylene (PTFE), perfluorinated ethylene propylene (FEP), poly ethylene, another suitable material or a combination thereof, but it is not limited thereto. Furthermore, the insulating layer 120 and/or the insulating layer 220 may have a single-layer or multi-layer structure. The material of the insulating layer 120 may be the same as or different from the material of the insulating layer 220.

Moreover, the electrode layer 130 and the electrode layer 230 may include a transparent conductive material. The transparent conductive material may include a transparent conductive oxide (TCO), such as indium tin oxide (ITO), antimony zinc oxide (AZO), tin oxide (SnO), zinc oxide (ZnO), indium zinc oxide (IZO), indium gallium zinc oxide (IGZO), indium tin zinc oxide (ITZO), antimony tin oxide (ATO), another suitable transparent conductive material or a combination thereof, but it is not limited thereto. Furthermore, the material of the electrode layer 130 may be the same as or different from the material of the electrode layer 230.

In accordance with some embodiments, the material of the spacer element 310 may include photoresist, but it is not limited thereto. The color filter layer 320 may be used to filter the optical properties of light passing through it, for example, to allow light in a specific wavelength range to pass. In accordance with some embodiments, the color filter layer 320 may include a red filter unit, a green filter unit, a blue filter unit or filter units of other colors, but it is not limited thereto. In accordance with different embodiments, the color filter layer 320 may have any suitable number or color of color filter units.

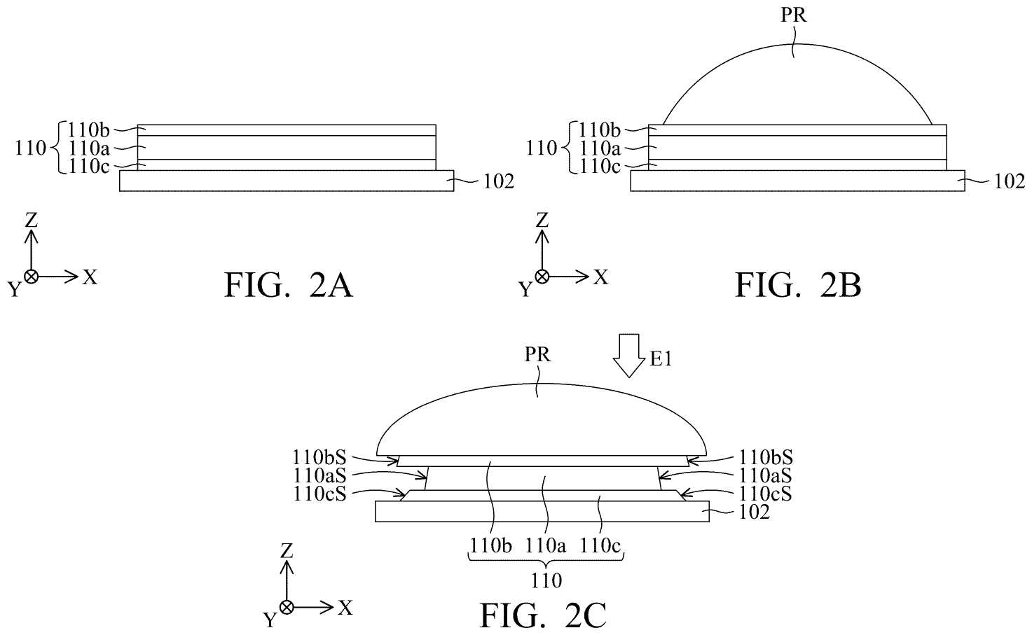

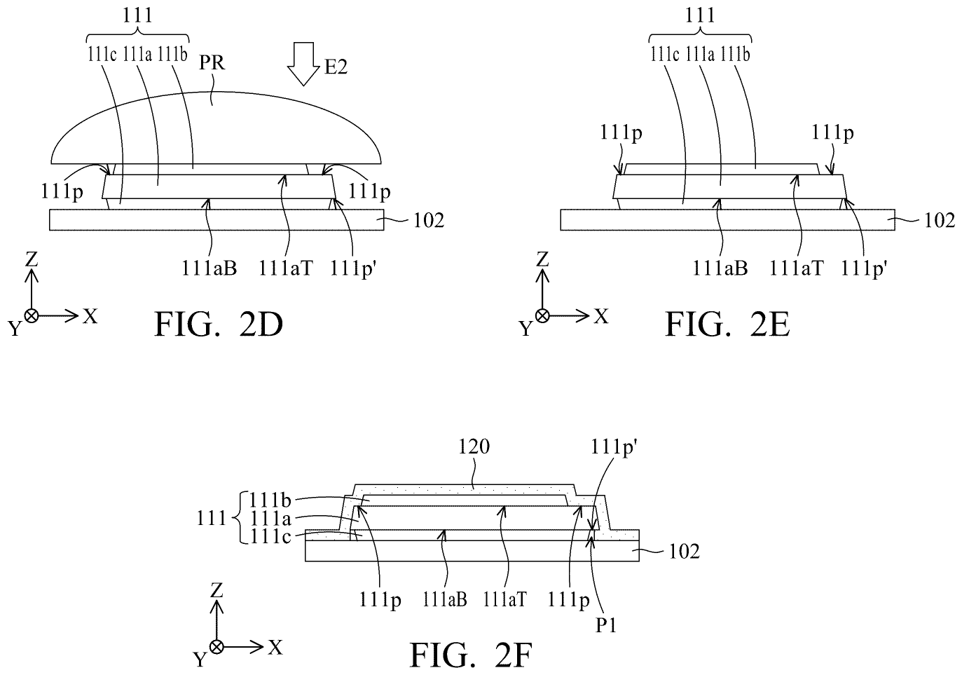

Next, please refer to FIGS. 2A to 2F, which are cross-sectional diagrams of some elements of an electronic device 10 during the intermediate stages of the manufacturing process in accordance with some embodiments of the present disclosure. Specifically, FIGS. 2A to 2F show cross-sectional diagrams of the composite conductive pattern 111 at the intermediate stages of the manufacturing process. It should be understood that the following description takes the composite conductive pattern 111 as an example, and the composite conductive pattern 211 can also be manufactured in the same or similar manner. In accordance with some embodiments, additional operations may be provided before, during, and/or after the method of manufacturing the electronic device 10. In accordance with some embodiments, some of the operations described may be replaced or deleted. In accordance with some embodiments, the order of the operations may be interchangeable.

First, referring to FIG. 2A, a substrate 102 is provided, and a composite conductive layer 110 is disposed on the substrate 102. In accordance with some embodiments, there may be other material layers (not illustrated) between the substrate 102 and the composite conductive layer 110. That is, before the composite conductive layer 110 is disposed, other material layers (not illustrated) may be formed on the substrate 102 first. The composite conductive layer 110 may have a plurality of conductive layers. As shown in FIG. 2A, in accordance with some embodiments, the composite conductive layer 110 may have three conductive layers, i.e. a first conductive layer 110a, a second conductive layer 110b and a third conductive layer 110c. The second conductive layer 110b may be disposed on the first conductive layer 110a, and the first conductive layer 110a may be disposed between the second conductive layer 110b and the third conductive layer 110c, but they are not limited thereto. The composite conductive layer 110 may be provided with at least two conductive layers according to needs. The composite conductive layer 110 may include a first conductive layer 110a and a second conductive layer 110b of different materials.

In accordance with some embodiments, the composite conductive layer 110 may have three conductive layers, the second conductive layer 110b and the third conductive layer 110c may have the same material or materials with similar properties, and the material of the first conductive layer 110a is different from the materials of the second conductive layer 110b and the third conductive layer 110c, but they are not limited thereto. In accordance with some embodiments, the etching rate of the second conductive layer 110b and/or the third conductive layer 110c is significantly different from the etching rate of the first conductive layer 110a under different etching solutions. In accordance with some embodiments, the material of the first conductive layer 110a may include aluminum, copper, chromium or another suitable material, and the material of the second conductive layer 110b and/or the third conductive layer 110c may include molybdenum oxide:tantalum (MoO:Ta), silicon oxynitride (SiNₓO_{y}), yttrium oxide alloy (Y₂O₃ alloy), chromium oxide (Cr₂O₃) or another suitable material, but they are not limited thereto. In accordance with some embodiments, the third conductive layer 110c, the first conductive layer 110a and the second conductive layer 110b may be sequentially formed on the substrate 102 through a chemical vapor deposition process, a physical vapor deposition process, an electroplating process, an electroless plating process, another suitable process, or a combination thereof, but it is not limited thereto. In accordance with some embodiments, the third conductive layer 110c may be optionally not provided. It should be understood that although the composite conductive layer 110 shown in the drawing has a three-layer structure, the present disclosure is not limited thereto. In accordance with some other embodiments, the composite conductive layer 110 may have two layers, four layers, five layers, or another suitable number of layers.

Next, referring to FIG. 2B, a photoresist PR is disposed on the composite conductive layer 110 to define the subsequent patterned shape of the composite conductive layer 110. In accordance with some embodiments, the pattern of the photoresist PR may be defined through a photolithography process.

Next, referring to FIG. 2C, a first wet etching process E1 is performed on the composite conductive layer 110 to remove a portion of the composite conductive layer 110. Specifically, the composite conductive layer 110 that is not shielded by the photoresist PR may be removed through the first wet etching process E1. It should be understood that the embodiments of the present disclosure take positive photoresist as an example for description, but they are not limited thereto. Negative photoresist can also be used for the patterning process with appropriate adjustments. Furthermore, the first wet etching process E1 may, for example, use an etching solution with a high etching selectivity for the first conductive layer 110a. In accordance with some embodiments, for example, aluminic acid or another etching solution with a high etching selectivity for the first conductive layer 110a may be used as the etching solution of the first wet etching process E1, but it is not limited thereto. As shown in FIG. 2C, compared with the second conductive layer 110b and/or the third conductive layer 110c, more of the first conductive layer 110a is removed by the first wet etching process E1, so that the side surface 110aS of the first conductive layer 110a is retracted inward from the side surface 110bS of the second conductive layer 110b and/or the side surface 110cS of the third conductive layer 110c.

Next, referring to FIG. 2D, the photoresist PR is still disposed on the composite conductive layer 110, a second wet etching process E2 is performed on the composite conductive layer 110, and a portion of the composite conductive layer 110 is removed again (referring to FIG. 2C) to form a composite conductive pattern 111. The composite conductive pattern 111 may include a first conductive pattern 111a, a second conductive pattern 111b and a third conductive pattern 111c. Specifically, the composite conductive layer 110 that is not shielded by the photoresist PR may be removed through the second wet etching process E2 (referring to FIG. 2C), but it is not limited thereto. The second wet etching process E2 may use an etching solution with a high etching selectivity for the second conductive layer 110b and/or the third conductive layer 110c. In accordance with some embodiments, for example, cupric acid or another etching solution with high etching selectivity for the second conductive layer 110b and/or the third conductive layer 110c may be used as the etching solution of the second wet etching process E2, but it is not limited thereto. As shown in FIG. 2D, compared with the first conductive layer 110a, more of the second conductive layer 110b and/or the third conductive layer 110c is removed by the second wet etching process E2. After performing the second wet etching process E2, the second conductive pattern 111b may expose a portion 111p of the first conductive pattern 111a. In detail, the second conductive pattern 111b may be disposed on the first conductive pattern 111a, and the second conductive pattern 111b may expose the portion 111p of the upper surface 111aT of the first conductive pattern 111a. Furthermore, in accordance with some embodiments, the first conductive pattern 111a may be disposed between the second conductive pattern 111b and the third conductive pattern 111c. After performing the second wet etching process E2, the third conductive pattern 111c may also expose a portion 111p′ of the conductive pattern 111a. In detail, the third conductive pattern 111c may expose the portion 111p′ of the lower surface 111aB of the first conductive pattern 111a.

As described above, the composite conductive layer 110 may be patterned into the composite conductive pattern 111 in two wet etching steps (the first E1 wet etching process and the second wet etching process E2), and the two wet etching steps use different etching solutions. One of the two wet etching steps uses an etching solution with a high etching selectivity for the first conductive layer 110a, and the other step uses an etching solution with a high etching selectivity for the second conductive layer 110b. In accordance with some embodiments, the different etching solutions may include aluminic acid and cupric acid, but they are not limited thereto.

Next, referring to FIG. 2E, the photoresist PR is removed. In accordance with some embodiments, the photoresist PR may be removed through a wet stripping process, a plasma ashing process, or a combination thereof, but it is not limited thereto.

Next, referring to FIG. 2F, an insulating layer 120 is disposed on the composite conductive pattern. The insulating layer 120 may cover the composite conductive pattern 111 and the substrate 102. As shown in FIG. 2F, the composite conductive pattern 111 may include the first conductive pattern 111a, the second conductive pattern 111b and/or the third conductive pattern 111c. The second conductive pattern 111b may be disposed on the first conductive pattern 111a and expose the portion 111p of the first conductive pattern 111a, and the insulating layer 120 may contact the portion 111p of the first conductive pattern 111a exposed by the second conductive pattern 111b. Furthermore, the first conductive pattern 111a may be disposed between the second conductive pattern 111b and the third conductive pattern 111c. In accordance with some embodiments, the third conductive pattern 111c may expose the portion 111p′ of the first conductive pattern 111a, and there may be, for example, a void P1 between the portion 111p′ of the first conductive pattern 111a, the insulating layer 120, the third conductive pattern 111c and the substrate 102, but it is not limited thereto. In accordance with some embodiments, the void P1 may, for example, serve as an expansion and contraction space of the composite conductive pattern 111, but it is not limited thereto.

In accordance with some embodiments, the insulating layer 120 may be formed on the composite conductive pattern 111 and the substrate 102 through a chemical vapor deposition process, a physical vapor deposition process, a coating process, a printing process, another suitable process, or a combination thereof.

It should be noted that through the aforementioned process, the overhang structure of the composite conductive pattern 111 caused by having multiple layers (e.g., the first conductive pattern 111a, the second conductive pattern 111b and the third conductive pattern 111c) with widely different etching rates may be improved. The problems such as cracks in the insulating layer 120 caused by the overhang structure, or short circuits due to breakage of the composite conductive pattern 111 and electrical connection with adjacent circuit elements may be reduced. Therefore, the structural reliability of the composite conductive pattern 111 may be improved.

In accordance with some embodiments, the reflectivity of the second conductive pattern 111b may be less than the reflectivity of the first conductive pattern 111a, and the reflectivity of the third conductive pattern 111c may be less than the reflectivity of the first conductive pattern 111a, thereby reducing the problem of light reflection from the conductive pattern affecting the display image of the electronic device.

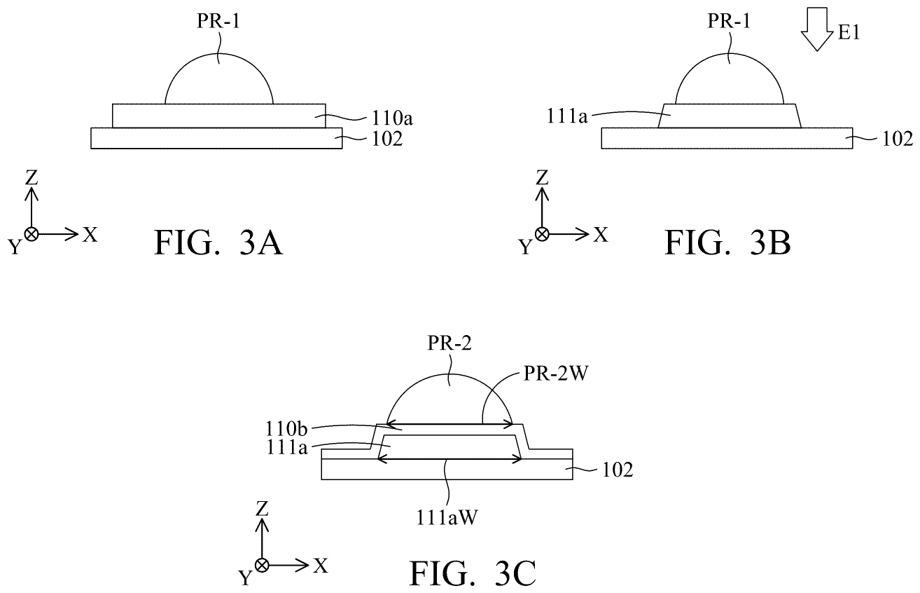

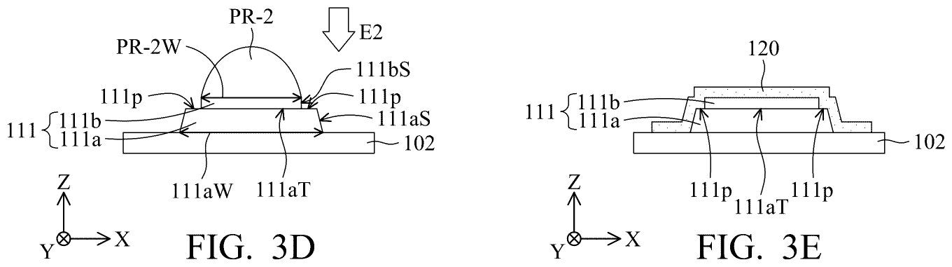

Please refer to FIGS. 3A to 3E, which are cross-sectional diagrams of some elements of the electronic device 10 during the intermediate stages of the manufacturing process in accordance with some other embodiments of the present disclosure. Specifically, FIGS. 3A to 3E show cross-sectional diagrams of the composite conductive pattern 111 at the intermediate stages of the manufacturing process. It should be understood that the same or similar components or elements in above and below contexts are represented by the same or similar reference numerals. The materials, manufacturing methods and functions of these components or elements are the same or similar to those described above, and thus will not be repeated in the following description.

First, referring to FIG. 3A, a substrate 102 is provided, and a first conductive layer 110a is disposed on the substrate 102. Then, a first photoresist PR-1 is disposed on the first conductive layer 110a to define the subsequent patterned shape of the first conductive layer 110a.

Next, referring to FIG. 3B, a first wet etching process E1 is performed on the first conductive layer 110a to remove a portion of the first conductive layer 110a to form a first conductive pattern 111a. Specifically, the first conductive layer 110a that is not shielded by the first photoresist PR-1 may be removed through the first wet etching process E1, but it is not limited thereto. The first wet etching process E1 may use an etching solution with a high etching selectivity for the first conductive layer 110a. In accordance with some embodiments, for example, aluminic acid or another etching solution with a high etching selectivity for the first conductive layer 110a may be used as the etching solution of the first wet etching process E1, but it is not limited thereto.

Next, refer to FIG. 3C. After removing the first photoresist PR-1 (as shown in FIG. 3B), a second conductive layer 110b is disposed on the first conductive pattern 111a. The second conductive layer 110b may cover the first conductive pattern 111a and the substrate 102. Next, a second photoresist PR-2 is disposed on the second conductive layer 110b to define the subsequent patterned shape of the second conductive layer 110b. In this embodiment, a width PR-2W (e.g., the maximum width) of the second photoresist PR-2 may be less than or equal to a width 111aW (e.g., the maximum width) of the first conductive pattern 111a, but it is not limited thereto. In accordance with some embodiments, in a top-view direction of the electronic device 10 (the Z direction), the projection of the second photoresist PR-2 onto the substrate 102 may be within the projection of the first conductive pattern 111a onto the substrate 102, but it is not limited thereto. In accordance with some embodiments, in a top-view direction of the electronic device 10 (the Z direction), the projected area of the second photoresist PR-2 onto the substrate 102 may be less than or equal to the projected area of the first conductive pattern 111a onto the substrate 102, but it is not limited thereto.

Next, referring to FIG. 3D, a second wet etching process E2 is performed on the composite conductive layer 110 to remove a portion of the second conductive layer 110b to form a second conductive pattern 111b. Specifically, the second conductive layer 110b that is not shielded by the second photoresist PR-2 may be removed through the second wet etching process E2, but it is not limited thereto. Furthermore, the second wet etching process E2 may use an etching solution with a high etching selectivity for the second conductive layer 110b. In accordance with some embodiments, for example, cupric acid or another etching solution with a high etching selectivity for the second conductive layer 110b may be used as the etching solution of the second wet etching process E2, but it is not limited thereto. As shown in FIG. 3D, after the second wet etching process E2 is performed, the second conductive pattern 111b may expose a portion 111p of the first conductive pattern 111a. In detail, the second conductive pattern 111b may expose the portion 111p of the upper surface 111aT of the first conductive pattern 111a, but it is not limited thereto. In accordance with some other embodiments (not illustrated), the second conductive pattern 111b may not expose the upper surface 111aT of the first conductive pattern 111a, for example, the side surface 111bS of the second conductive pattern 111b may be substantially aligned with the side surface 111aS of the first conductive pattern 111a.

As described above, in this embodiment, the composite conductive layer 110 has a two-layer structure (the first conductive layer 110a and the second conductive layer 110b), and the composite conductive layer 110 may also be patterned into the composite conductive pattern 111 in two wet etching steps (the first E1 wet etching process and the second wet etching process E2). The two wet etching steps use different etching solutions for etching. That is, the etching solution of the first wet etching process E1 is different from the etching solution of the second wet etching process E2.

Next, referring to FIG. 3E, the second photoresist PR-2 is removed and an insulating layer 120 is disposed on the composite conductive pattern 111. The insulating layer 120 may cover the composite conductive pattern 111 and the substrate 102. As shown in FIG. 3E, in this embodiment, the composite conductive pattern 111 may include the first conductive pattern 111a and the second conductive pattern 111b. The second conductive pattern 111b may be disposed on the first conductive pattern 111a and expose a portion 111p of the first conductive pattern 111a, and the insulating layer 120 may contact the portion 111p of the first conductive pattern 111a exposed by the second conductive pattern 111b.

It should be noted that through the aforementioned process, the overhang structure of the composite conductive pattern 111 caused by having multiple layers (e.g., the first conductive pattern 111a and the second conductive pattern 111b) with widely different etching rates may be improved. The problems such as cracks in the insulating layer 120 caused by the overhang structure, or short circuits due to electrical connection with adjacent circuit elements may be reduced. Therefore, the structural reliability of the composite conductive pattern 111 may be improved, but it is not limited thereto.

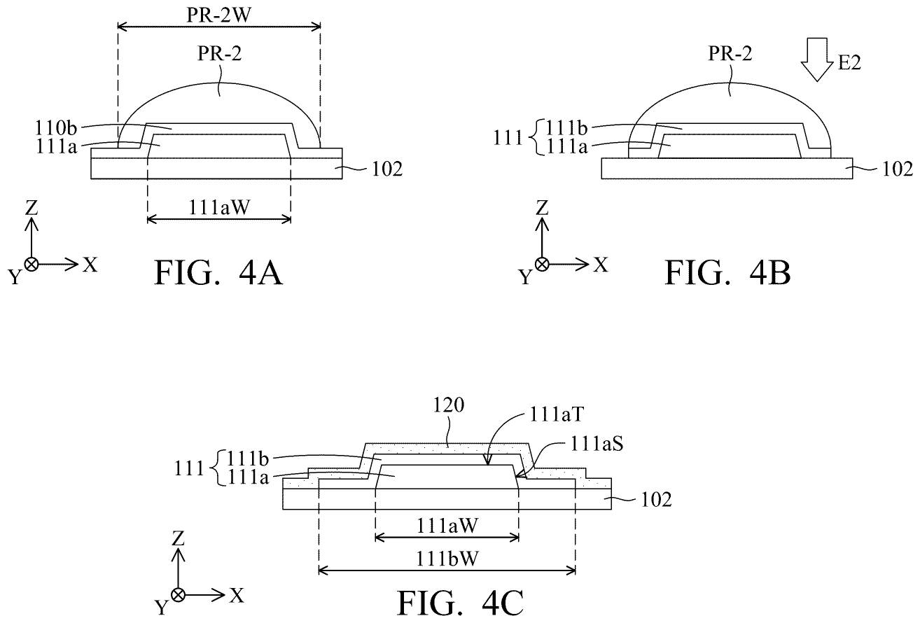

Please refer to FIGS. 4A to 4C, which are cross-sectional diagrams of some elements of the electronic device 10 during the intermediate stages of the manufacturing process in accordance with some other embodiments of the present disclosure. Specifically, FIGS. 4A to 4C show cross-sectional diagrams of the composite conductive pattern 111 at the intermediate stages of the manufacturing process.

Please refer to FIG. 4A. FIG. 4A may substantially continue the steps of FIG. 3B. Specifically, before the steps of FIG. 4A, the following steps are performed (similar to FIG. 3A): a substrate 102 is provided; a first conductive layer 110a is disposed on the substrate 102, and then a first photoresist PR-1 is disposed on the first conductive layer 110a. Next, similar to FIG. 3B, a first wet etching process E1 is performed on the first conductive layer 110a to remove a portion of the first conductive layer 110a to form the first conductive pattern 111a; and after the first photoresist PR-1 is removed, the second conductive layer 110b is disposed on the first conductive pattern 111a, and the second conductive layer 110b may cover the first conductive pattern 111a and the substrate 102. Next, as shown in FIG. 4A, a second photoresist PR-2 is disposed on the second conductive layer 110b to define the subsequent patterned shape of the second conductive layer 110b. In this embodiment, a width PR-2W (e.g., the maximum width) of the second photoresist PR-2 may be greater than a width 111aW (e.g., the maximum width) of the first conductive pattern 111a. In accordance with some embodiments, in a top-view direction of the electronic device 10 (the Z direction), the projection of the first conductive pattern 111a onto the substrate 102 may be within the projection of the second photoresist PR-2 onto the substrate 102, but it is not limited thereto. In accordance with some embodiments, in a top-view direction of the electronic device 10 (the Z direction), the projected area of the second photoresist PR-2 onto the substrate 102 may be larger than the projected area of the first conductive pattern 111a onto the substrate 102, but it is not limited thereto.

Next, referring to FIG. 4B, a second wet etching process E2 is performed on the composite conductive layer 110 to remove a portion of the second conductive layer 110b to form a second conductive pattern 111b. Specifically, the second conductive layer 110b that is not shielded by the second photoresist PR-2 may be removed through the second wet etching process E2, but it is not limited thereto. Furthermore, the second wet etching process E2 may use an etching solution with a high etching selectivity for the second conductive layer 110b. In accordance with some embodiments, for example, cupric acid or another etching solution with a high etching selectivity for the second conductive layer 110b may be used as the etching solution of the second wet etching process E2, but it is not limited thereto.

As described above, in this embodiment, the composite conductive layer 110 has a two-layer structure (the first conductive layer 110a and the second conductive layer 110b), and the composite conductive layer 110 may also be patterned into the composite conductive pattern 111 in two wet etching steps (the first E1 wet etching process and the second wet etching process E2). The two wet etching steps use different etching solutions for etching.

Next, referring to FIG. 4C, the second photoresist PR-2 (as shown in FIG. 4B) is removed, and an insulating layer 120 is disposed on the composite conductive pattern 111. The insulating layer 120 may cover the composite conductive pattern 111 and the substrate 102. As shown in FIG. 4C, in this embodiment, the composite conductive pattern 111 may include the first conductive pattern 111a and the second conductive pattern 111b, and the insulating layer 120 may contact the second conductive pattern 111b and the substrate 102, but not contact the first conductive pattern 111b, but it is not limited thereto. In this embodiment, a width 111bW (e.g., the maximum width) of the second conductive layer 111b may be greater than a width 111aW (e.g., the maximum width) of the first conductive layer 111a. In this embodiment, the second conductive layer 111b may be disposed on or cover the upper surface 111aT and the side surface 111aS of the first conductive layer 111a. In accordance with some embodiments, the second conductive layer 111b may selectively contact a portion of the substrate 102 or other material layers (not illustrated) formed between the substrate 102 and the first conductive layer 111a.

It should be noted that through the aforementioned process, the overhang structure of the composite conductive pattern 111 caused by having multiple layers (e.g., the first conductive pattern 111a and the second conductive pattern 111b) with widely different etching rates may be improved. The problems such as cracks in the insulating layer 120 caused by the overhang structure, or short circuits due to electrical connection with adjacent circuit elements may be reduced. Therefore, the structural reliability of the composite conductive pattern 111 may be improved, but it is not limited thereto.

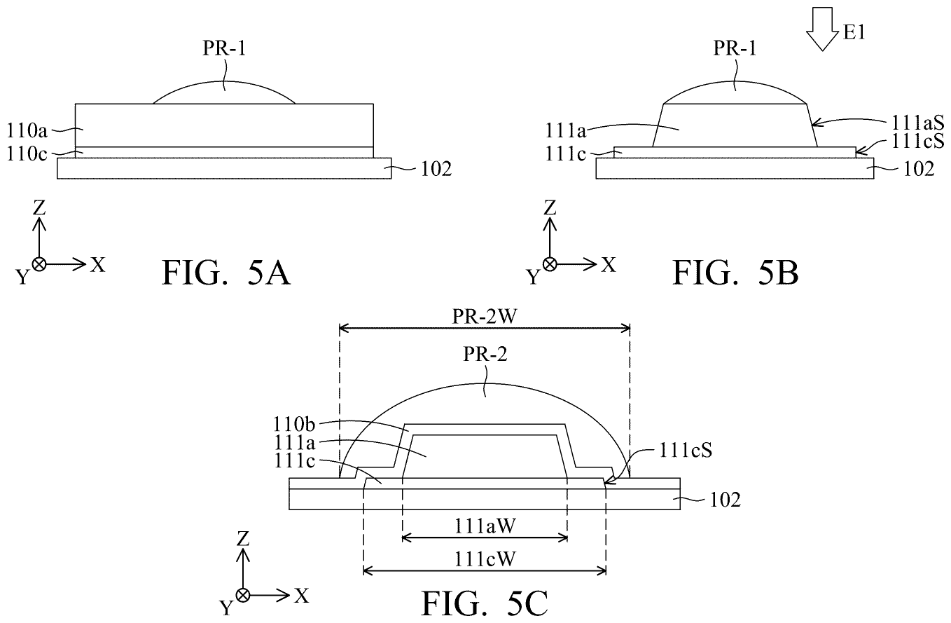

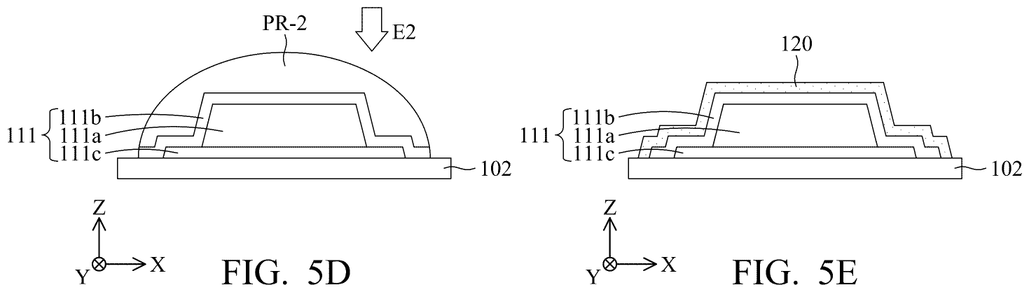

Please refer to FIGS. 5A to 5E, which are cross-sectional diagrams of some elements of the electronic device 10 during the intermediate stages of the manufacturing process in accordance with some other embodiments of the present disclosure. Specifically, FIGS. 5A to 5E show cross-sectional diagrams of the composite conductive pattern 111 at the intermediate stages of the manufacturing process.

First, referring to FIG. 5A, a substrate 102 is provided, and a third conductive layer 110c and a first conductive layer 110a are sequentially disposed on the substrate 102. Then, a first photoresist PR-1 is disposed on the first conductive layer 110a to define the subsequent patterned shapes of the first conductive layer 110a and the third conductive layer 110c.

Next, referring to FIG. 5B, a first wet etching process E1 is performed on the first conductive layer 110a and the third conductive layer 110c to remove portions of the first conductive layer 110a and the third conductive layer 110c. Specifically, the first conductive layer 110a and the third conductive layer 110c that are not shielded by the first photoresist PR-1 may be removed through the first wet etching process E1, but they are not limited thereto. The first wet etching process E1 may use an etching solution with a high etching selectivity for the first conductive layer 110a. In accordance with some embodiments, for example, aluminic acid or another etching solution with a high etching selectivity for the first conductive layer 110a may be used as the etching solution of the first wet etching process E1, but it is not limited thereto. As shown in FIG. 5B, compared with the third conductive layer 110c, more of the first conductive layer 110a is removed by the first wet etching process E1, so that the side surface 111cS of the third conductive pattern 111c may protrude from the side surface 111aS of the first conductive pattern 111a after the etching process.

Next, refer to FIG. 5C. After the first photoresist PR-1 (as shown in FIG. 5B) is removed, a second conductive layer 110b is disposed on the first conductive pattern 111a. The second conductive layer 110b may cover the first conductive pattern 111a, the third conductive pattern 111c and/or the substrate 102, and the second conductive layer 110b may contact the side surface 111cS of the third conductive pattern 111c. Next, a second photoresist PR-2 is disposed on the second conductive layer 110b to define the subsequent patterned shape of the second conductive layer 110b. In this embodiment, a width PR-2W (e.g., the maximum width) of the second photoresist PR-2 may be greater than a width 111aW (e.g., the maximum width) of the first conductive pattern 111a and/or a width 111cW (e.g., the maximum width) of the third conductive pattern 111c. In this embodiment, the width 111aW of the first conductive pattern 111a may be less than or equal to the width 111cW of the third conductive pattern 111c. In accordance with some embodiments, in a top-view direction of the electronic device 10 (the Z direction), the projection of the first conductive pattern 111a onto the substrate 102 may be within the projection of the second photoresist PR-2 onto the substrate 102, but it is not limited thereto. In accordance with some embodiments, in a top-view direction of the electronic device 10 (the Z direction), the projection of the third conductive pattern 111c onto the substrate 102 may be within the projection of the second photoresist PR-2 onto the substrate 102, but it is not limited thereto. In accordance with some embodiments, in a top-view direction of the electronic device 10 (the Z direction), the projected area of the second photoresist PR-2 onto the substrate 102 may be larger than the projected area of the first conductive pattern 111a onto the substrate 102 and/or the projected area of the third conductive pattern 111a onto the substrate 102, but it is not limited thereto.

Next, referring to FIG. 5D, a second wet etching process E2 is performed to remove a portion of the second conductive layer 110b to form a second conductive pattern 111b. Specifically, the second conductive layer 110b that is not shielded by the second photoresist PR-2 may be removed through the second wet etching process E2, but it is not limited thereto. Furthermore, the second wet etching process E2 may use an etching solution with a high etching selectivity for the second conductive layer 110b. In accordance with some embodiments, for example, cupric acid or another etching solution with a high etching selectivity for the second conductive layer 110b may be used as the etching solution of the second wet etching process E2, but it is not limited thereto.

As described above, in this embodiment, the composite conductive layer 110 has a three-layer structure (the first conductive layer 110a, the second conductive layer 110b and the third conductive layer 110c), but it is not limited thereto. The composite conductive layer 110 may also be patterned into the composite conductive pattern 111 in two wet etching steps (the first E1 wet etching process and the second wet etching process E2). The two wet etching steps use different etching solutions for etching.

Next, referring to FIG. 5E, the second photoresist PR-2 (as shown in FIG. 5D) is removed, and an insulating layer 120 is disposed on the composite conductive pattern 111. The insulating layer 120 may cover the composite conductive pattern 111 and/or the substrate 102. As shown in FIG. 5E, in this embodiment, the composite conductive pattern 111 may include the first conductive pattern 111a, the second conductive pattern 111b and the third conductive pattern 111c, and the insulating layer 120 may contact the second conductive pattern 111b and/or the substrate 102, but not contact the first conductive pattern 111a and/or the third conductive pattern 111c. In accordance with some other embodiments (not illustrated), the insulating layer 120 may contact other material layers (not illustrated) disposed between the substrate 102 and the composite conductive pattern 111. In this embodiment, the first conductive layer 110a may be, for example, covered between the second conductive pattern 111b and the third conductive pattern 111c. It should be noted that through the aforementioned process, the overhang structure of the composite conductive pattern 111 caused by having multiple layers (e.g., the first conductive pattern 111a, the second conductive pattern 111b and the third conductive pattern 111c) with widely different etching rates may be improved. The problems such as cracks in the insulating layer 120 caused by the overhang structure, or short circuits due to electrical connection with adjacent circuit elements may be reduced. Therefore, the structural reliability of the composite conductive pattern 111 may be improved, but it is not limited thereto.

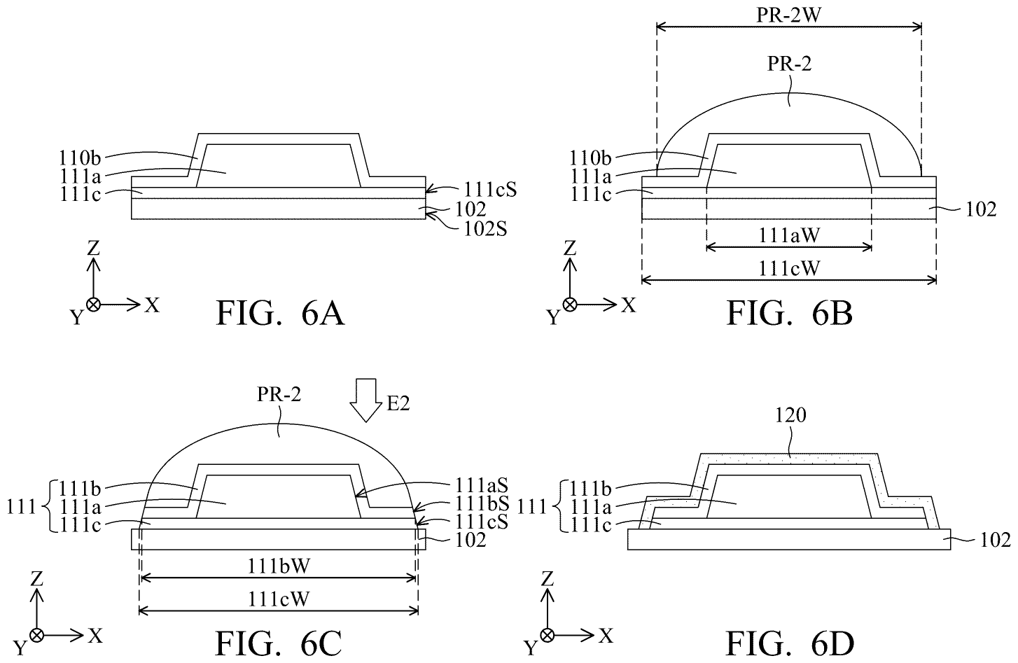

Please refer to FIGS. 6A to 6D, which are cross-sectional diagrams of some elements of the electronic device 10 during the intermediate stages of the manufacturing process in accordance with some other embodiments of the present disclosure. Specifically, FIGS. 6A to 6D show cross-sectional diagrams of the composite conductive pattern 111 at the intermediate stages of the manufacturing process.

First, please refer to FIG. 6A. FIG. 6A may substantially continue the steps of FIG. 5B. Specifically, before the steps of FIG. 6A, the following steps are performed. A substrate 102 is provided. A third conductive layer 110c and a first conductive layer 110a are sequentially disposed on the substrate 102. A first photoresist PR-1 is disposed on the first conductive layer 102 to define the subsequent patterned shape of the first conductive layer 110a and/or the third conductive layer 110c. A first wet etching process E1 is performed on the first conductive layer 110a and/or the third conductive layer 110c to remove portions of the first conductive layer 110a and the third conductive layer 110c. The first photoresist PR-1 is removed. However, in this embodiment, the wet etching solution used in the first wet etching process E1 may, for example, have an insignificant etching effect on the third conductive layer 110c. Therefore, the side surface 111cS of the third conductive pattern 111c may be substantially aligned with the side surface 102S of the substrate 102, but it is not limited thereto. Then, as shown in FIG. 6A, a second conductive layer 110b is disposed on the first conductive pattern 111a. The second conductive layer 110b may cover the first conductive pattern 111 and the third conductive pattern 111c. Moreover, the side surface (not labeled) of the second conductive layer 110 may be substantially aligned with the side surface 111cS of the third conductive pattern 111c.

Next, referring to FIG. 6B, a second photoresist PR-2 is disposed on the second conductive layer 110b to define the subsequent patterned shape of the second conductive layer 110b. In this embodiment, a width PR-2W (e.g., the maximum width) of the second photoresist PR-2 may be greater than a width 111aW (e.g., the maximum width) of the first conductive pattern 111a. In this embodiment, a width PR-2W (e.g., the maximum width) of the second photoresist PR-2 may be less than or equal to a width 111cW (e.g., the maximum width) of the third conductive pattern 111c. In accordance with some embodiments, in a top-view direction of the electronic device 10 (the Z direction), the projection of the first conductive pattern 111a onto the substrate 102 may be within the projection of the second photoresist PR-2 onto the substrate 102, but it is not limited thereto. In accordance with some embodiments, the projection of the second photoresist PR-2 onto the substrate 102 may be located within the projection of the third conductive pattern 111c onto the substrate 102, but it is not limited thereto. In accordance with some embodiments, the projected area of the second photoresist PR-2 onto the substrate 102 may be larger than the projected area of the first conductive pattern 111a onto the substrate 102, but it is not limited thereto. In accordance with some embodiments, the projected area of the second photoresist PR-2 onto the substrate 102 may be smaller than the projected area of the third conductive pattern 111c onto the substrate 102, but it is not limited thereto.

Next, referring to FIG. 6C, a second wet etching process E2 is performed to remove a portion of the second conductive layer 110b to form a second conductive pattern 111b, and also remove a portion of the third conductive pattern 111c. Specifically, the second conductive layer 110b and/or the third conductive pattern 111c that are not shielded by the second photoresist PR-2 may be removed through the second wet etching process E2, but it is not limited thereto. Furthermore, the second wet etching process E2 may use an etching solution with a high etching selectivity for the second conductive layer 110b and/or the third conductive pattern 111c. In accordance with some embodiments, for example, cupric acid or another etching solution with high etching selectivity for the second conductive layer 110b and/or the third conductive pattern 111c may be used as the etching solution for the second wet etching process E2, but it is not limited thereto. In this embodiment, after the second wet etching process E2 is performed, the side surface 111bs of the second conductive pattern 111b may be substantially aligned with the side surface 111cs of the third conductive pattern 111c. In this embodiment, a width 111cW of the third conductive pattern 111c may be greater than or equal to a width 111bW of the second conductive pattern 111b. In accordance with some embodiments, the materials of the second conductive pattern 111b and the third conductive pattern 111c may be the same or different. In this embodiment, the first conductive layer 110a may be, for example, covered between the second conductive pattern 111b and the third conductive pattern 111c.

As described above, in this embodiment, the composite conductive layer 110 has a three-layer structure (the first conductive layer 110a, the second conductive layer 110b and the third conductive layer 110c), and the composite conductive layer 110 may also be patterned into the composite conductive pattern 111 in two wet etching steps (the first E1 wet etching process and the second wet etching process E2). In addition, the two wet etching steps use different etching solutions for etching.

Next, referring to FIG. 6D, the second photoresist PR-2 (as shown in FIG. 6C) is removed, and an insulating layer 120 is disposed on the composite conductive pattern 111. The insulating layer 120 may cover the composite conductive pattern 111 and the substrate 102. As shown in FIG. 6D, in this embodiment, the composite conductive pattern 111 may include the first conductive pattern 111a, the second conductive pattern 111b and the third conductive pattern 111c, and the insulating layer 120 may contact the second conductive pattern 111b, the third conductive pattern 111c and/or the substrate 102, but not contact the first conductive pattern 111a. In accordance with some other embodiments (not illustrated), the insulating layer 120 may contact other material layers disposed between the composite conductive pattern 111 and the substrate 102.

It should be noted that through the aforementioned process, the overhang structure of the composite conductive pattern 111 caused by having multiple layers (e.g., the first conductive pattern 111a, the second conductive pattern 111b and the third conductive pattern 111c) with widely different etching rates may be improved. The problems such as cracks in the insulating layer 120 caused by the overhang structure, or short circuits due to electrical connection with adjacent circuit elements may be reduced. Therefore, the structural reliability of the composite conductive pattern 111 may be improved.

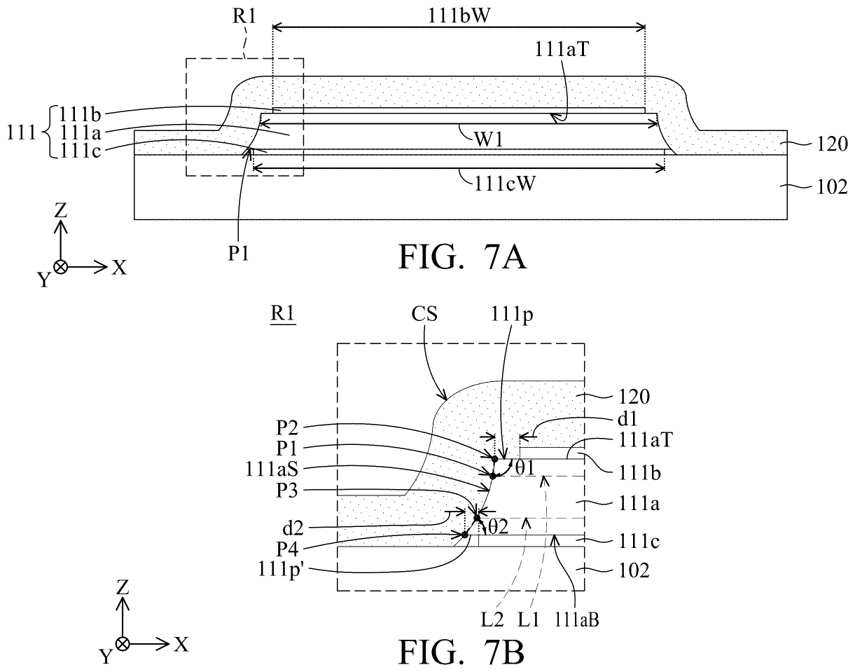

Next, please refer to FIG. 7A and FIG. 7B, which are cross-sectional diagrams of some elements of the electronic device 10 in accordance with some embodiments of the present disclosure. FIG. 7A and FIG. 7B will further illustrate the specific structure of the electronic device 10 formed by the manufacturing method of the aforementioned embodiments (for example, the method shown in FIGS. 2A to 2F), which shows the cross-sectional diagrams of the substrate 102, the composite conductive pattern 111 and the insulating layer 120 of the electronic device 10. FIG. 7B is a partial enlarged diagram of region R1 of FIG. 7A.

As shown in FIG. 7A and FIG. 7B, the electronic device 10 may include a substrate 102, a composite conductive pattern 111 and an insulating layer 120. The composite conductive pattern 111 may be disposed on the substrate 102. The insulating layer 120 may be disposed on the composite conductive pattern 111 (e.g., on the second conductive pattern 111b). It should be noted that other material layers (not illustrated) may be selectively disposed between the composite conductive pattern 111 and the substrate 102. In accordance with some embodiments, the composite conductive pattern 111 may include a first conductive pattern 111a, a second conductive pattern 111b, and a third conductive pattern 111c. The second conductive pattern 111b may be disposed on the first conductive pattern 111a, and the first conductive pattern 111a may be disposed between the second conductive pattern 111b and the third conductive pattern 111c. In accordance with some other embodiments (not illustrated), other material layers (such as other conductive or non-conductive material layers) may be selectively inserted between the first conductive pattern 111a, the second conductive pattern 111b and the third conductive pattern 111c.

In accordance with some embodiments, in a top-view direction of the electronic device 10 (the Z direction), the thickness of the first conductive pattern 111a may be greater than the thickness of the second conductive pattern 111b, and the thickness of the first conductive pattern 111a may be greater than the thickness of the third conductive pattern 111c. In accordance with some embodiments, in a top-view direction of the electronic device 10 (the Z direction), the thickness of the insulating layer 120 may be greater than the thickness of the second conductive pattern 111b and/or the thickness of the third conductive pattern 111c. In accordance with some embodiments, in a top-view direction of the electronic device 10 (the Z direction), the thickness of the insulating layer 120 may be less than or equal to the thickness of the first conductive pattern 111a. In accordance with some embodiments, the thickness of the first conductive pattern 111a may be between 1000 angstrom (Å) and 12000 Å, or between 2000 Å and 11000 Å, or between 3000 Å and 10000 Å, for example, 4000 Å, 5000 Å, 6000 Å, 7000 Å, 8000 Å or 9000 Å, but it is not limited thereto. In accordance with some embodiments, the thickness of the second conductive pattern 111b may be between 100 Å and 2000 Å, or between 200 Å and 1500 Å, for example, 300 Å, 400 Å, 500 Å, 600 Å, 700 Å, 800 Å, 900 Å, 1000 Å, 1100 Å, 1200 Å, 1300 Å or 1400 Å, but it is not limited thereto. In accordance with some embodiments, the thickness of the third conductive pattern 111c may be between 100 Å and 2000 Å, or between 200 Å and 1500 Å, for example, 300 Å, 400 Å, 500 Å, 600 Å, 700 Å, 800 Å, 900 Å, 1000 Å, 1100 Å, 1200 Å, 1300 Å or 1400 Å, but it is not limited thereto. In accordance with some embodiments, the thickness of the insulating layer 120 may be between 1000 Å and 6000 Å, or between 1500 Å and 5500 Å, for example, 2000 Å, 2500 Å, 3000 Å, 3500 Å, 4000 Å, 4500 Å or 5000 Å, but it is not limited thereto.

The thicknesses of the first conductive pattern 111a, the second conductive pattern 111b, the third conductive pattern 111c and the insulating layer 120 respectively refer to the average thickness of three arbitrary points of the first conductive pattern 111a, the second conductive pattern 111b, the third conductive pattern 111c and the insulating layer 120 in the normal direction of the substrate 102 (for example, the Z direction in the drawing) in a cross section.

In accordance with some embodiments, the reflectivity of the second conductive pattern 111b may be less than the reflectivity of the first conductive pattern 111a, and the reflectivity of the third conductive pattern 111c may be less than the reflectivity of the first conductive pattern 111a. That is, the second conductive pattern 111b and/or the third conductive pattern 111c on both sides of the first conductive pattern 111a may have a relatively small reflectivity. With this configuration, the problem of light being reflected by the conductive pattern and affecting the display image of the electronic device can be reduced. In accordance with some embodiments, the second conductive pattern 111b and/or the third conductive pattern 111c may include, for example, blackened metal or another low-reflective conductive material, but they are not limited thereto.

Furthermore, the second conductive pattern 111b may expose a portion 111p of the upper surface 111aT of the first conductive pattern 111a. The insulating layer 120 may be disposed on the second conductive pattern 111b and contact the portion 111p of the upper surface 111aT of the first conductive pattern 111a exposed by the second conductive pattern 111b. In particular, the upper surface 111aT of the first conductive pattern 111a may have a first surface width W1 and the portion 111p exposed by the second conductive pattern 111b may have a first width d1, and the first width d1 and the first surface width W1 comply with the following formula: 0<the first width d1≤the first surface width W1×⅕, but it is not limited thereto. That is, the first width d1 may be greater than 0 and less than or equal to ⅕ times the first surface width W1. In accordance with some embodiments, the first width d1 and the first surface width W1 comply with the following formula: 0<the first width d1≤the first surface width W1×⅛. In accordance with some embodiments, the first width d1 and the first surface width W1 comply with the following formula: 0<the first width d1≤the first surface width W1× 1/10. In accordance with some embodiments, the first width d1 and the first surface width W1 comply with the following formula: 0<the first width d1≤the first surface width W1× 1/15.

It should be noted that when the first width d1 of the first conductive pattern 111a is greater than 0, the first conductive pattern 111a and the second conductive pattern 111b have a ladder-like structure, thereby improving the contact area between the first conductive pattern 111a/second conductive pattern 111b and the insulating layer 120. The adhesion between the film layers can be improved. On the other hand, if the first width d1 of the first conductive pattern 111a is greater than ⅕ times the first surface width W1, the size of the second conductive pattern 111b may be too small to effectively provide a light-shielding effect.

Moreover, the third conductive pattern 111c may expose a portion 111p′ of the lower surface 111aB of the first conductive pattern 111a. In accordance with some embodiments, a void P1 may exist between the portion 111p′ of the first conductive pattern 111a, the insulating layer 120, the third conductive pattern 111c and the substrate 102, but it is not limited thereto. In addition, the portion 111p′ of the lower surface 111aB of the first conductive pattern 111a may have a second width d2, and the first width d1 of the first conductive pattern 111a may be greater than the second width d2 (i.e. the first width d1>the second width d2). In accordance with some embodiments, the ratio of the first width d1 to the second width d2 may be between 1 and 20 (1<the first width d1/the second width d2≤20), but it is not limited thereto. In accordance with some embodiments, the ratio of the first width d1 to the second width d2 may be between 1 and 15 (1<the first width d1/the second width d2≤15). In accordance with some embodiments, the ratio of the first width d1 to the second width d2 may be between 1 and 10 (1<the first width d1/the second width d2≤10). In accordance with some embodiments, the ratio of the first width d1 to the second width d2 may be between 1 and 5 (1<the first width d1/the second width d2≤5).

It should be noted that if the second width d2 is greater than the first width d1, a large void may be generated when the insulating layer 120 covers the composite conductive pattern 111, which may affect the reliability of the composite conductive pattern 111. Furthermore, the third conductive pattern 111c may have a maximum width 111cW, and the second conductive pattern 111b may have a maximum width 111bW. In accordance with some embodiments, the maximum width 111cW of the third conductive pattern 111c may be greater than the maximum width 111bW of the second conductive pattern 111b. The aforementioned maximum width 111cW refers to the maximum width of the third conductive pattern 111c in a direction (e.g., the X direction in the drawing) perpendicular to the normal direction of the substrate 102 (e.g., the Z direction in the drawing), and the maximum width 111b refers to the maximum width of the second conductive pattern 111b in a direction perpendicular to the normal direction of the substrate 102 (e.g. the X direction in the drawing).

In addition, the first conductive pattern 111a may have an arc-shaped side surface 111aS (for example, a concave arc, a wavy arc, or an irregular arc), and the insulating layer 120 may contact the arc-shaped side surface 111aS. The arc-shaped side surface 111aS may increase the adhesion area between the insulating layer 120 and the first conductive pattern 111a, so as to improve the adhesion between them. In accordance with some embodiments (not illustrated), the first conductive pattern 111a may have a relatively flat side surface 111aS (that is, the profile of the side surface 111aS is close to a straight line in a cross-section). Furthermore, there may be a first included angle θ1 between the side surface 111aS and the upper surface 111aT of the first conductive pattern 111a, and there may be a second included angle θ2 between the side surface 111aS and the lower surface 111aB of the first conductive pattern 111a. In accordance with some embodiments (not illustrated), when the first conductive pattern 111a has an arc-shaped side surface 111aS, the measurement method of the first included angle θ1 and the second included angle θ2 can be defined as follows. In the Z direction, the height of the lower surface 111aB of the first conductive pattern 111a is defined as 0 and the height of the upper surface 111aT is defined as 1, a virtual line L1 parallel to the X direction is drawn at a height of approximately 0.7, and a virtual line L2 parallel to the X direction is drawn at a height of approximately 0.3. The virtual line L1 and the side surface 111aS may intersect at a point P1, and a virtual line can be drawn between the point P1 and an end point P2 of the upper surface 111aT. The included angle between this virtual line (as shown in the drawing) and the upper surface 111aT is a first included angle θ1. Similarly, the virtual line L2 and the side surface 111aS may intersect at a point P3, and a virtual line can be drawn between the point P3 and an end point P4 of the lower surface 111aB. The included angle between this virtual line (as shown in the drawing) and the lower surface 111aB is a second included angle θ2. In accordance with some embodiments (not illustrated), if the first conductive pattern 111a has a relatively flat side surface 111aS, the first included angle θ1 and the second included angle θ2 can also be obtained using a similar method as above. In accordance with some embodiments, the first included angle θ1 may be greater than 90 degrees and less than 145 degrees (i.e. 90 degrees<the first included angle θ1<145 degrees), but it is not limited thereto. In accordance with some embodiments, the first included angle θ1 may be greater than 90 degrees and less than 120 degrees (i.e. 90 degrees<the first included angle θ1<120 degrees), but it is not limited thereto. In accordance with some embodiments, the first included angle θ1 may be greater than the second included angle θ2. In accordance with some embodiments, the surface of the insulating layer 120 may have an arc-shaped edge CS.

It should be noted that when the first included angle θ1 is greater than 90 degrees, the insulating layer 120 disposed on the composite conductive pattern 111 is less likely to break. On the other hand, if the first included angle θ1 is greater than 145 degrees, the composite conductive pattern 111 may be too wide and the aperture ratio of the electronic device may be reduced. Furthermore, when the first included angle θ1 is greater than the second included angle θ2, the adhesion between the insulating layer 120 and the composite conductive pattern 111 may be improved and the risk of cracking or damage of the insulating layer 120 may be reduced.

To summarize the above, in accordance with the embodiments of the present disclosure, the method of manufacturing an electronic device uses etching steps of different etching solutions to form a composite conductive pattern, thereby improving the overhang structure produced by the composite conductive pattern having multiple layers with widely different etching rates. The method further reduces problems such as cracks in the insulating layer or short circuits caused by electrical connections with adjacent circuit elements caused by the overhang structure, thereby improving the structural reliability of the composite conductive pattern.

Although some embodiments of the present disclosure and their advantages have been described in detail, it should be understood that various changes, substitutions and alterations can be made herein without departing from the spirit and scope of the disclosure as defined by the appended claims. The features of the various embodiments can be used in any combination as long as they do not depart from the spirit and scope of the present disclosure. Moreover, the scope of the present application is not intended to be limited to the particular embodiments of the process, machine, manufacture, composition of matter, means, methods and steps described in the specification. As one of ordinary skill in the art will readily appreciate from the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Thus, the appended claims are intended to include within their scope such processes, machines, manufacture, compositions of matter, means, methods or steps. Moreover, each claim constitutes an individual embodiment, and the claimed scope of the present disclosure includes the combinations of the claims and embodiments. The scope of protection of the present disclosure is subject to the definition of the scope of the appended claims. Any embodiment or claim of the present disclosure does not need to meet all the purposes, advantages, and features disclosed in the present disclosure.

What is claimed is:

1. A method of manufacturing an electronic device, comprising:
providing a substrate;
disposing a composite conductive layer on the substrate; and
patterning the composite conductive layer into a composite conductive pattern in two wet etching steps, wherein the two wet etching steps use different etching solutions for etching.

2. The method of manufacturing an electronic device as claimed in claim 1, wherein the composite conductive layer comprises a first conductive layer and a second conductive layer of different materials, one of the two wet etching steps uses an etching solution with a high etching selectivity for the first conductive layer, and the other of the two wet etching steps uses an etching solution with a high etching selectivity for the second conductive layer.

3. The method of manufacturing an electronic device as claimed in claim 2, wherein the different etching solutions comprise aluminic acid and cupric acid.

4. The method of manufacturing an electronic device as claimed in claim 1, further comprising:
disposing an insulating layer on the composite conductive pattern, wherein the composite conductive pattern comprises a first conductive pattern and a second conductive pattern, the second conductive pattern is disposed on the first conductive pattern and exposes a portion of the first conductive pattern, and the insulating layer contacts the portion of the first conductive pattern exposed by the second conductive pattern.

5. The method of manufacturing an electronic device as claimed in claim 1, wherein the composite conductive pattern comprises a first conductive pattern and a second conductive pattern, the second conductive pattern is disposed on the first conductive pattern, and a reflectivity of the second conductive pattern is less than a reflectivity of the first conductive pattern.

6. The method of manufacturing an electronic device as claimed in claim 2, wherein the composite conductive layer further comprises a third conductive layer, the first conductive layer is disposed between the second conductive layer and the third conductive layer, and the materials of the first conductive layer and the third conductive layer are different.

7. The method of manufacturing an electronic device as claimed in claim 6, wherein the other of the two wet etching steps uses the etching solution with a high etching selectivity for the third conductive layer.

8. The method of manufacturing an electronic device as claimed in claim 1, wherein a material of the first conductive layer comprises aluminum, copper, chromium or a combination thereof.

9. The method of manufacturing an electronic device as claimed in claim 1, wherein a material of the second conductive layer comprises molybdenum oxide:tantalum (MoO:Ta), silicon oxynitride (SiNₓO_{y}), yttrium oxide alloy (Y₂O₃ alloy), chromium oxide (Cr₂O₃) or a combination thereof.

10. An electronic device, comprising:
a substrate;
a composite conductive pattern disposed on the substrate, comprising:
a first conductive pattern; and
a second conductive pattern disposed on the first conductive pattern, wherein the second conductive pattern exposes a portion of an upper surface of the first conductive pattern; and
an insulating layer disposed on the second conductive pattern and contacting the portion of the upper surface of the first conductive pattern exposed by the second conductive pattern, wherein the upper surface of the first conductive pattern has a first surface width, the portion exposed by the second conductive pattern has a first width, and the first width and the first surface width comply with the following formula:
0<the first width≤the first surface width×⅕.

11. The electronic device as claimed in claim 10, wherein the first conductive pattern has an arc-shaped side surface, and the insulating layer contacts the arc-shaped side surface.

12. The electronic device as claimed in claim 10, wherein a first included angle between a side surface and the upper surface of the first conductive pattern is greater than 90 degrees and less than 145 degrees.

13. The electronic device as claimed in claim 10, wherein a first included angle between a side surface and the upper surface of the first conductive pattern is greater than a second included angle between the side surface and a lower surface of the first conductive pattern.

14. The electronic device as claimed in claim 10, wherein the composite conductive pattern further comprises a third conductive pattern, the first conductive pattern is disposed between the second conductive pattern and the third conductive pattern, and a reflectivity of the second conductive pattern and a reflectivity of the third conductive pattern is less than a reflectivity of the first conductive pattern.

15. The electronic device as claimed in claim 10, wherein the composite conductive pattern further comprises a third conductive pattern, the first conductive pattern is disposed between the second conductive pattern and the third conductive pattern, the third conductive pattern exposes a portion of a lower surface of the first conductive pattern, the portion of the lower surface of the first conductive pattern has a second width, and the first width is greater than the second width.

16. The electronic device as claimed in claim 15, wherein a ratio of the first width to the second width is between 1 and 20.

17. The electronic device as claimed in claim 10, wherein the composite conductive pattern further comprises a third conductive pattern, the first conductive pattern is disposed between the second conductive pattern and the third conductive pattern, and a maximum width of the third conductive pattern is greater than a maximum width of the second conductive pattern.

18. The electronic device as claimed in claim 10, wherein the composite conductive pattern further comprises a third conductive pattern, the first conductive pattern is disposed between the second conductive pattern and the third conductive pattern, the third conductive pattern exposes a portion of a lower surface of the first conductive pattern, and there is a void between the portion of the lower surface of the first conductive pattern, the insulating layer, the third conductive pattern and the substrate.

19. The electronic device as claimed in claim 10, wherein a surface of the insulating layer has an arc-shaped edge.

20. The electronic device as claimed in claim 10, wherein a thickness of the insulating layer is greater than a thickness of the second conductive pattern.
